(19) United States
(12) Patent Application Publication
(10) Pub. No.: US 2006/0001111 A1
(43) Pub. Date: Jan. 5, 2006

(54) Semiconductor device

(75) Inventors: Ryuta Tsuchiya, Hachioji (JP); Shinichi Sato, Kawasaki (JP); Masatada Horiuchi, Koganei (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/155,674

(22) Filed: Jun. 20, 2005

(30) Foreign Application Priority Data
Jun. 21, 2004 (JP) 2004-182489

(51) Int. Cl. H01L 29/76; H01L 21/8238

(52) U.S. Cl. 257/410; 257/411; 257/412; 257/413; 438/216; 438/591; 257/351; 438/154

(57) ABSTRACT

In a full depletion MISFET, there is a limit to control on a threshold voltage Vth by an impurity concentration in principle when a monocrystalline SOI layer becomes thin on the order of a few tens of nm. It was thus difficult to simultaneously realize predetermined Vth of both n and p types in a complementary MISFET. A gate insulating film for the MISFET is formed as a laminated layer of a metal oxide and an oxynitride. A gate electrode is formed using a polycrystalline Si semiconductor film of the same conductivity type as a source-drain. Predetermined Vth for enhancement are simultaneously achieved by a shift of a flatband voltage produced between the gate insulating film and the gate electrode made of the semiconductor film. Since a variation in Vth due to a statistical fluctuation in the number of impurities with respect to one MISFET can be reduced as compared with the case in which each Vth is controlled by the impurity concentration, Vth and a power supply voltage can both be set low.

### CLAIM OF PRIORITY

The present application claims priority from Japanese application JP 2004-182489 filed on Jun. 21, 2004, the content of which is hereby incorporated by reference into this application.

### FIELD OF THE INVENTION

The present invention relates to a semiconductor device, and particularly to a MISFET (Metal/Insulator/Semiconductor Field Effect Transistor) having an SOI (Silicon on Insulator) structure.

### BACKGROUND OF THE INVENTION

With high integration of an LSI and an increase in its performance, the miniaturization of each MISFET has recently been under way and the scaling of its gate length has been done. Therefore, a problem about a short channel effect that a threshold voltage Vth is reduced comes to the fore. The short channel effect results from the fact that spreading of a depletion layer at source and drain portions of the MISFET exerts an influence even on a channel portion with miniaturization of a channel length. It is considered that in order to prevent such an influence, the impurity concentration of the channel portion is made high and the spreading of the depletion layer at the source and drain portions is suppressed. However, a problem arises in that when the impurity concentration of the channel portion is made high, degradation of a drive current occurs due to a reduction in carrier mobility with an increase in impurity scattering. When the impurity concentration is made high, parasitic capacitance between a substrate and a source and drain will increase, thus leading to interference with high-speed operations of the MISFETs.

The threshold voltages Vth of these MISFETs have heretofore been controlled by the impurity concentrations of their channel regions. The control by the impurity concentration of each channel has been done relatively satisfactorily by taking advantage of an ion-implantation technique and a short-time thermal treatment technique, up to an LSI based on a design rule of about 100 nm node.

However, in a MISFET based on a finer design rule of a 100 nm node or from the 100 nm node on down, the absolute number of impurities contributing to a threshold voltage Vth of a per one MISFET is reduced as a channel length becomes short in a method for controlling a threshold voltage Vth according to the amount of impurities in a channel. Therefore, a variation in threshold voltage Vth due to a statistical fluctuation cannot be neglected and hence the threshold voltage Vth cannot be controlled (refer to, for example, a non-patent document 1 (T. Mizuno et al., “Performance Fluctuations of 0.10 μm MOSFETs—Limitation of 0.10 μm ULSIs”, Symposium on VLSI Technology Digest of Technical Papers, pp. 13-14, 1994)).

In order to solve such a problem, attention has recently been focused on an SOI structure. Since complete isolation is done by an insulating film in the structure, soft errors and latch up are suppressed and high reliability is obtained even in an LSI having a high degree of integration. In addition, since a diffusion layer is reduced in junction capacitance, charge and discharge with switching are less reduced. Thus, the present structure is advantageous even to speeding up and attainment of low power dissipation.

The present SOI MISFET has two operation modes roughly divided into two. One corresponds to a full depletion SOI wherein a depletion layer induced in a body region directly below a gate electrode reaches the bottom face of the body region, i.e., an interface with a buried oxide film. Another one corresponds to a partial depletion SOI wherein a depletion layer does not reach a bottom face of a body region and a neutral region remains.

Since the thickness of the depletion layer directly below the gate is restricted dependent on the buried oxide film in the full depletion SOI-MISFET, a depletion electrical charge is drastically reduced as compared with the partial depletion SOI-MISFET. Instead, a movable electrical charge that contributes to a drain current increases. As a result, the full depletion SOI-MISFET has the advantage that a steep subthreshold characteristic (S characteristic) is obtained.

That is, when the steep S characteristic is obtained, a threshold voltage Vth can be reduced while an off leakage current is being suppressed. As a result, a MISFET extremely low in power dissipation can be fabricated which ensures a drain current even at a low operating voltage, and is operated at, for example, 1V or less (threshold voltage Vth also aims at 0.3V or less, 0.1V in the present specification).

Although the problem about the above short channel effect arises in the case of a MISFET fabricated on a normal semiconductor silicon substrate, the substrate and the elemental devices are separated from one another in the full depletion SOI-MISFET and hence no depletion layer is spread. Therefore, the full depletion SOI-MISFET can be reduced in substrate concentration. Thus, since a reduction in carrier mobility with an increase in impurity scattering is suppressed, a high-driven current-carrying operation can be achieved. Further, a variation in threshold voltage Vth due to a statistical fluctuation in the number of impurities with respect to one MISFET can be reduced as compared with the method for controlling the threshold voltage Vth by the impurity concentration.

On the other hand, there is a limit to control on the threshold voltage Vth by the impurity concentration in principle in the full depletion SOI-MISFET because a monocrystalline SOI layer is thin on the order of about a few tens of nm. Since carrier mobility is reduced due to an increase in impurity scattering when the impurity concentration of the channel portion is set to, for example, a concentration of 1×10¹⁸ cm⁻³ or more, current drive capacity is degraded and an increase in the dependence of the thickness of the SOI layer on the threshold voltage Vth cannot be neglected.

Thus, it has been desired as a micro MISFET-compatible process that in addition to the control on the channel portion by the impurity concentration, the threshold voltage Vth of the MISFET can be controlled even depending on work functions of gate electrode materials (metal electrode materials in addition to the conventionally used n-type semiconductor film gate electrode material and p-type semiconductor film electrode material).

There is known, for example, a report about a case in which an n-type polycrystalline silicon gate electrode material is used for an n channel MISFET and a p-type polycrystalline silicon gate electrode material is used for a p channel MISFET to fabricate a full depletion SOI-MISFET (refer to, for example, a non-patent document 2 (B. Doris et al., “Extreme Scaling with Ultra-Thin Si Channel MOSFETs” IEDM Tech., pp. 267-270, 2002)).

There is also known a report about a case in which a p-type polycrystalline silicon gate electrode material is used for an n channel MISFET and an n-type polycrystalline silicon gate electrode material is used for a p channel MISFET to fabricate a full depletion SOI-MISFET (refer to, for example, a non-patent document 3 (T. Tanigawa et al., “Enhancement of Data Retention Time for Giga-bit DRAMs Using SIMOX Technology” Symp. on VLSI Technology, pp. 37-38, 1994)).

There is also known another report that a gate electrode is formed of a metal material and a threshold voltage Vth of a full depletion SOI-MISFET is controlled using a work function of the metal material (refer to, for example, a non-patent document 4 (J-M. Hwang et al., “Novel Polysilicon/TiN Stacked-Gate Structure for Fully-Depleted SOI/CMOS” IEDM Tech. Digest, pp. 345-348, 1992 and a non-patent document 5 (H. Shimada et al., “Threshold Voltage Adjustment in SOI MISFETs by Employing Tantalum for Gate Material”, IEDM Tech. Digest, pp. 881-884, 1995)).

Further, there is known a construction in which alumina (Al₂O₃) corresponding to a high-K material is used as a metal oxide gate insulating film, and an oxide film (SiO₂) or silicon oxynitride film (SiON) is provided at an interface between a silicon substrate and the metal oxide gate insulating film to suppress a leakage current (refer to, for example, a patent document 1 (Japanese Patent Laid-Open No. 2003-069011)).

Furthermore, there is known a case in which in order to obtain an enhancement thin-film SOI device having an n-type polysilicon gate, a gate oxide film for an n channel MOSFET is immersed in an Al solution containing Al of 1000 ppm to thereby enable formation of a negative fixed electrical charge by AL in the gate oxide film (refer to, for example, Japanese Patent Laid-Open No. H4(1992)-037168)).

### SUMMARY OF THE INVENTION

However, a problem arises in that the threshold voltages Vth of the n channel MISFET and p channel MISFET cannot be simultaneously realized under the work-function control by the metal electrode material in addition to the conventionally-used n-type polycrystalline silicon gate electrode material and p-type polycrystalline silicon gate electrode material.

Its details will be explained below. Incidentally, although a description will be made, as an example, of a MOSFET using an oxide film as a gate insulating film for each MISFET, it is needless to say that this example is by no means limited to the MOSFET.

FIG. 3A (corresponding to FIG. 6 in the non-patent document 2) is a static characteristic (hereinafter called “Ids-Vgs characteristic”) of a drain-source current (hereinafter called simply “drain current”) Ids vs. a gate-source voltage (hereinafter called simply “gate voltage”) where an oxide film is used for an n channel MISFET as a gate insulating film, and n-type polysilicon is used as a gate electrode material to thereby fabricate a full depletion SOI-n channel MOSFET (hereinafter called “nMOS”). The present figure shows characteristics at the time that a voltage Vds (hereinafter called simply “drain voltage”) applied between the drain and source is 1.2V and 0.05V. The horizontal axis indicates the gate voltage Vgs (V), and the vertical axis indicates the drain current Ids. An arrow indicated by a in the figure shows a target gate voltage (threshold voltage) at the time that when the drain voltage Vds is 1.2V, for example, a drain current Ids of 1 nA flows. However, an enhancement MOSFET having a threshold voltage of 0.1V is not obtained and an nMOS whose threshold voltage is a depletion type, is given as indicated by arrow b.

FIG. 3B (corresponding to FIG. 2 in the non-patent document 2) is an Ids-Vgs characteristic at the time that a full depletion SOI-pMOS is fabricated using a p-type polycrystalline silicon gate electrode material for a p channel MOSFET (hereinafter called “pMOS”). In a manner similar to the nMOS, the threshold voltage of an enhancement pMOS having a threshold voltage of −0.1V taken as a target indicated by a in the figure is not obtained, and a depletion type is given as indicated by arrow b.

Thus, when the polycrystalline silicon gate electrode materials are used, both nMOS and pMOS are respectively brought to a depletion type as is clear from FIGS. 3A and 3B, and their threshold voltages become values smaller than a predetermined threshold voltage Vth necessary for a normal circuit. As a result, a problem arises in that an off-leakage current increases significantly.

Next, examples (refer to the non-patent document 3) in which control on the threshold voltages of full depletion SOI-MOSFETs have been attempted using a p-type polycrystalline silicon gate electrode material for an nMOS and using an n-type polycrystalline silicon gate electrode material for a pMOS, are shown in FIGS. 4A and 4B. The same figures show Id-Vgs characteristics of the fabricated MOSFETs. Since an increase in threshold voltage is enabled in this case, enhancement MOSFETs can be fabricated for both nMOS and pMOS.

Here, about 1.1V exists as the difference in work function between the n-type polycrystalline silicon gate electrode material and the p-type polycrystalline silicon gate electrode material. That is, when the p-type polycrystalline silicon gate electrode material is used in the case of the nMOS, for example, the threshold voltage Vth thereof is increased like about 1.1V and hence shifted to the high threshold voltage Vth side as compared with the case in which the n-type polycrystalline silicon gate electrode material is used. Therefore, a problem arises in that the threshold voltage becomes a value larger than a predetermined threshold voltage Vth necessary for a normal circuit, so that a drive current is reduced.

On the other hand, various attempts to form a gate electrode with a metal material and control a threshold voltage Vth of each full depletion SOI-MISFET using a work function of the metal material have also been made. For example, an SOI-CMOS in which TiN is applied as a metal gate electrode material has been disclosed in the non-patent document 4. FIG. 5 shows a drain current Ids-gate voltage Vgs characteristic of a full depletion SOI-MOSFET using TiN shown in FIG. 2 of the non-patent document 4. The threshold voltage of an nMOS at the time that Ids=1 nA is 0.4V, and the threshold voltage of a pMOS thereat is −0.5V. It is understood that even in this case, a threshold voltage Vth, which is 0.1V as a target absolute value, cannot be simultaneously realized with respect to both nMOS and pMOS.

This results from the essential problem that since the threshold voltage Vth of the MOSFET is inevitably determined by a device structure (channel impurity concentration, thickness of gate insulating film, etc.) of the MOSFET when the material for the gate electrode is decided, only the MOSFET having one kind of threshold voltage Vth can barely be fabricated where the gate electrode is merely formed of a metal.

Therefore, there is a drawback that when an attempt to simultaneously set both nMOS and pMOS to target threshold voltages respectively is made, there is a need to apply metal materials respectively having individual work functions to both nMOS and pMOS, whereby a process grows complicated. A basic problem also exists in that since the metal material is used for the gate electrode, consistency with the conventional process lacks.

As mentioned above, the full depletion SOI-MISFET encounters difficulties in simultaneously controlling the threshold voltages Vth of the n channel MISFET and p channel MISFET.

The present invention has been made in view of the conventional problems. An object of the present invention is to provide a semiconductor device capable of simultaneously controlling threshold voltages Vth of an n channel MISFET and a p channel MISFET.

The present invention is based on the result found out by the present inventors, that when a gate insulating film for each MISFET is formed using a metal oxide film starting with Al₂O₃ or HfO₂, the following new phenomena take place. This will be explained below.

FIGS. 6A and 6B show capacitance (C)-voltage (V) measured results (hereinafter called “C-V curves”) of MISFETs each fabricated using Al₂O₃ as a metal oxide gate insulating film. Here, as described in the patent document 1, the gate electrode structure in which degradation of mobility is suppressed, is provided by forming the oxynitride film at the interface between the silicon substrate and the metal oxide gate insulating film. As gate electrode materials, n-type polycrystalline silicon is used for an n channel MISFET (hereinafter called “nMISFET”) and p-type polycrystalline silicon is used for a p channel MISFET (hereinafter called “pMISFET”).

It is understood from FIGS. 6A and 6B that the actually-measured C-V curves (circle marks) of the pMISFET and nMISFET are respectively significantly shifted from C-V curves (solid lines) predicted from the results of calculations as indicated by arrows s1 and s2, and flatband voltage shifts occur in both nMISFET and pMISFET.

The results of measurements of shift amounts of flatband voltages VFB at the time that Al₂O₃/SiO₂ is used for a gate insulating film were +0.44V in the case of the nMISFET and −0.25V in the case of the pMISFET. That is, when Al₂O₃ is used in the gate insulating film, a flatband voltage of an nMISFET and a flatband voltage of a pMISFET are respectively shifted in different directions as in the case of a positive direction (negative charge) as shown in FIG. 7A and a negative direction (positive charge) as shown in FIG. 7B. Incidentally, black circles in FIGS. 7A and 7B respectively indicate threshold voltages Vth at the time that SiO₂ is used in the gate insulating film.

When, for example, the gate oxide film is immersed in the solution of aluminum (Al), the negative fixed electrical charge −Qss (negative charge) by Al can be formed in the film as disclosed in the patent document 2, for example. That is, it is known that the threshold voltage Vth of the nMISFET can be shifted in a positive direction (enhancement direction). However, when the negative fixed electrical charge −Qss (negative charge) produced in the film by Al is applied to a pMISFET, the threshold voltage Vth of the pMISFET is shifted in a positive direction due to a negative charge, i.e., a depletion direction, thereby increasing an off-leakage current. This is a behavior opposite to the shifting of the pMISFET, based on the aforementioned preset results of experiments in the negative direction.

Here, it has been confirmed from the experimental results that even though the thickness of Al₂O₃ corresponding to the metal oxide gate insulating film, and the thickness of the oxynitride film corresponding to the interfacial layer are changed, the shifted amounts of flatband voltages remain unchanged.

It is considered from the above results that each of the fixed electrical charges that generate the flatband voltage shifts occurs in the interface between the metal oxide film and the gate electrode existent thereabove without existing in the metal oxide film or oxynitride. Further, the fixed electrical charges each generated at the interface shift the flatband voltage of the nMISFET and the flatband voltage of the pMISFET in the different directions, respectively as in the case of the positive direction (negative charge) and the negative direction (positive charge). Therefore, the threshold voltages Vth of both nMISFET and pMISFET can be shifted in the same enhancement direction and controlled simultaneously. The present invention has been made by the above findings obtained by the present inventors.

One example of a representative means for attaining the object of the present invention will be shown as follows: A semiconductor device according to the present invention comprises a field effect transistor including a semiconductor substrate; a semiconductor layer formed on the semiconductor substrate with an insulating film interposed therebetween; source and drain regions formed in the semiconductor layer; a channel region formed between the source and drain regions; a gate insulating film formed over the channel region; and a gate electrode formed through the gate insulating film, wherein the gate insulating film is a gate insulating film formed using a metal oxide having a dielectric constant higher than a silicon oxide film, and wherein the gate electrode has a structure in which a semiconductor film having the same conductivity type as the source and drain regions, and a high melting-point metal film are superimposed in sequence.

Here, a high melting-point metal silicide film may be used in place of the high melting-point metal film.

The semiconductor film is suitable if used as a polycrystalline silicon film.

### BRIEF DESCRIPTION OF THE DRAWINGS

FIG. 1 is a cross-sectional view of a MISFET showing a first embodiment of a semiconductor device according to the present invention;

FIG. 2A is a cross-sectional view for describing a process for manufacturing the MISFET showing the first embodiment;

FIG. 2B is a cross-sectional view of the MISFET, for describing the following manufacturing process of FIG. 2A;

FIG. 2C is a cross-sectional view of the MISFET, for describing the following manufacturing process of FIG. 2B;

FIG. 3A is a characteristic diagram showing the relationship between a drain current of a conventional nMOS and a gate voltage thereof;

FIG. 3B is a characteristic diagram illustrating the relationship between a drain current of a conventional pMOS and a gate voltage thereof;

FIG. 4A is a characteristic diagram depicting the relationship between a drain current of another conventional nMOS and a gate voltage thereof;

FIG. 4B is a characteristic diagram showing the relationship between a drain current of another conventional pMOS and a gate voltage thereof;

FIG. 5 is a characteristic diagram depicting the relationship between drain currents of a conventional further nMOS and a conventional further pMOS and gate voltages thereof;

FIG. 6A is a C-V curve of a pMISFET fabricated using a metal oxide gate insulating film;

FIG. 6B is a C-V curve of an nMISFET fabricated using a metal oxide gate insulating film;

FIG. 7A is a view showing a threshold voltage of an nMISFET fabricated using a metal oxide gate insulating film and a flatband voltage shift amount thereof;

FIG. 7B is a view illustrating a threshold voltage of a pMISFET fabricated using a metal oxide gate insulating film and a flatband voltage shift amount thereof;

FIG. 8 is a view showing the relationship between an equivalent oxide thickness and a gate leakage current;

FIG. 9 is a cross-sectional view of a MISFET showing a second embodiment of a semiconductor device according to the present invention;

FIG. 10 is a cross-sectional view of a complementary MISFET showing a third embodiment of a semiconductor device according to the present invention; and

FIG. 11 is a cross-sectional view of a complementary MISFET illustrating a fourth embodiment of a semiconductor device according to the present invention.

### DETAILED DESCRIPTION OF THE PREFERRED EMBODIMENTS

Several preferred embodiments of semiconductor devices according to the present invention will hereinafter be described in detail with reference to the accompanying drawings. Incidentally, essential parts are shown in enlarged form as compared with other parts in the respective cross-sectional views. The quality of materials for respective parts, conductivity type thereof and their manufacturing conditions, etc. are not limited to the descriptions of the present embodiments. It is needless to say that various changes in design can be made.

### First Preferred Embodiment

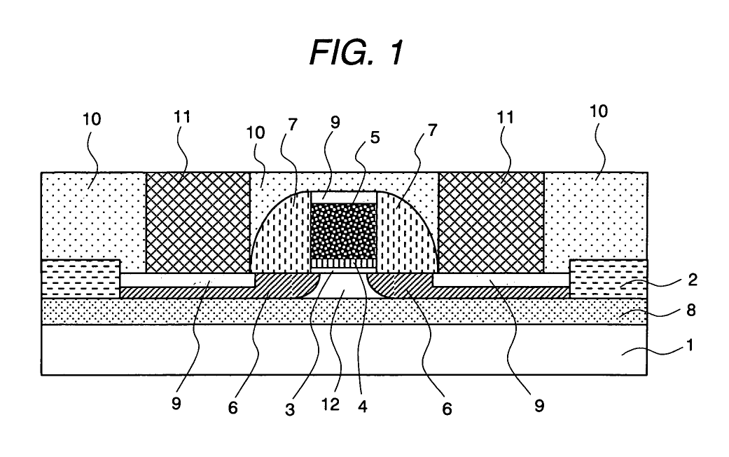

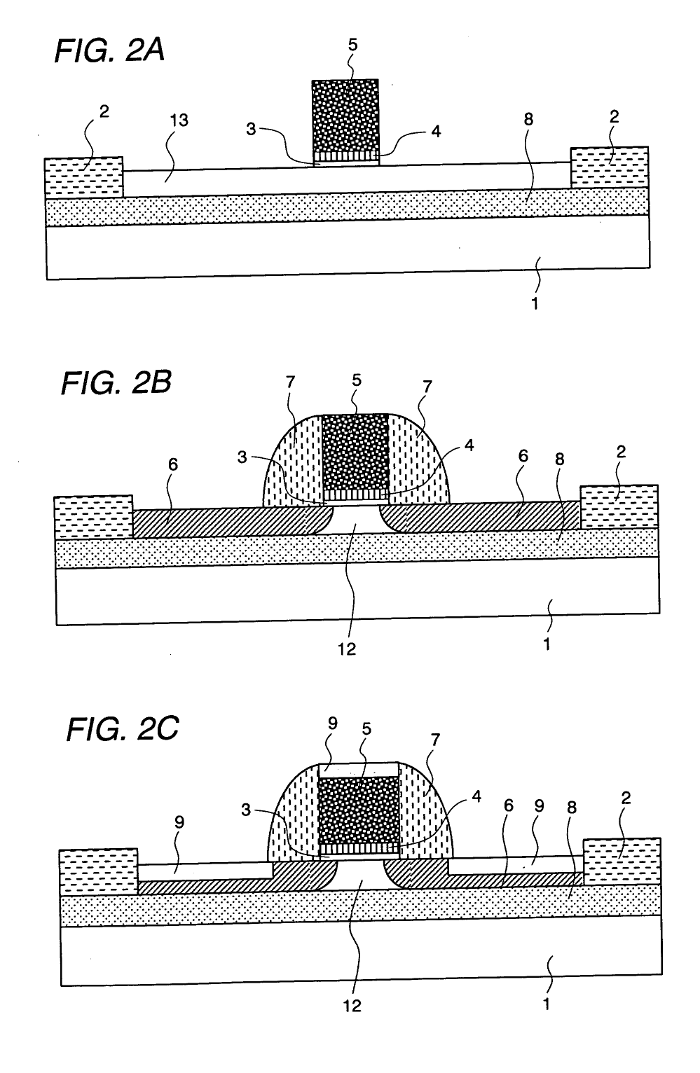

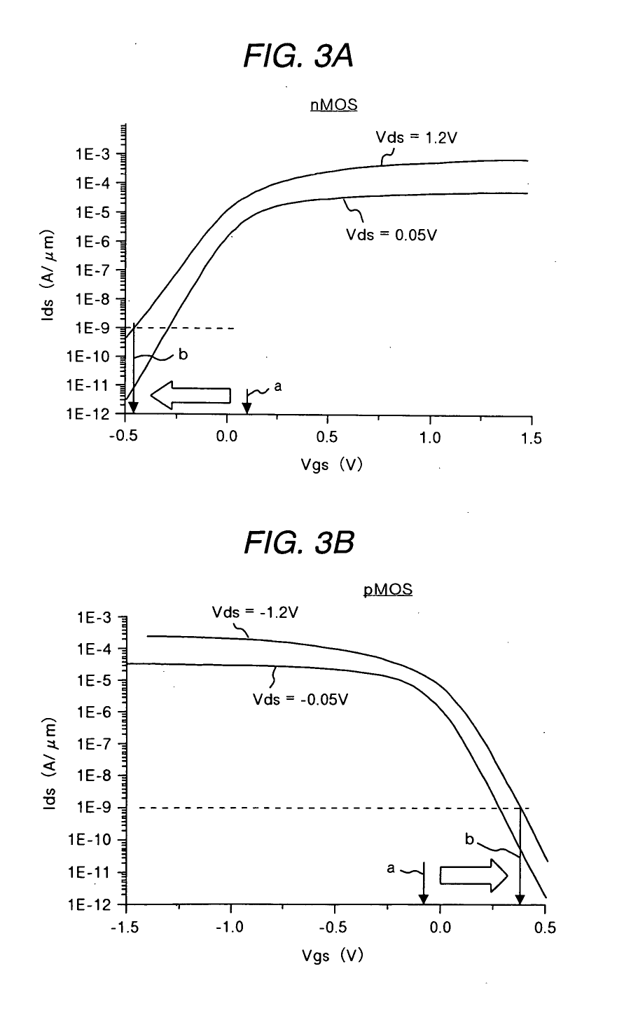

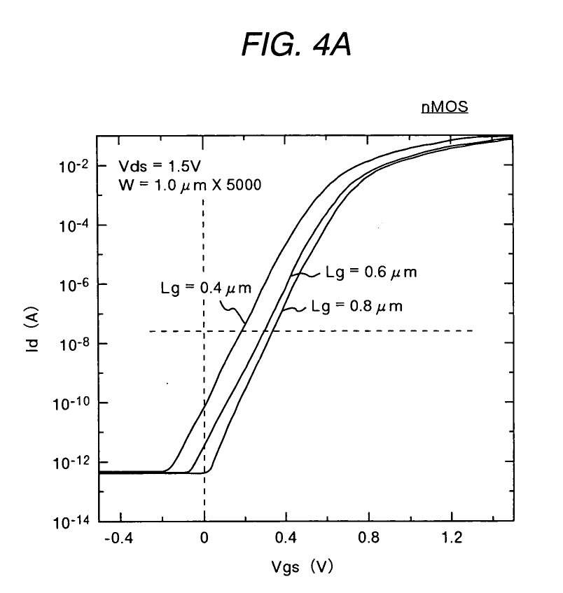

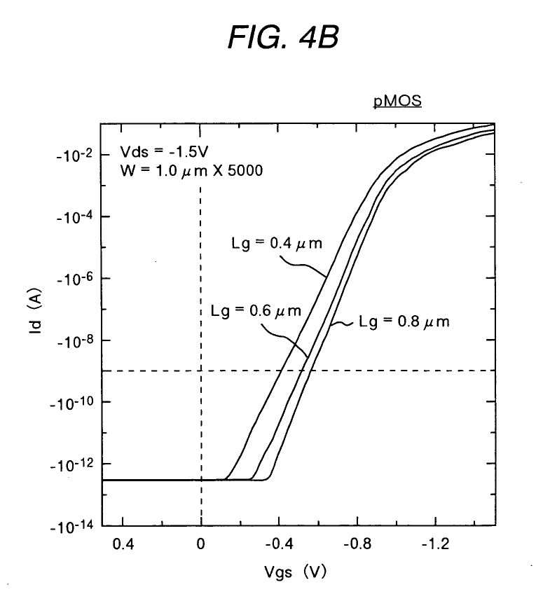

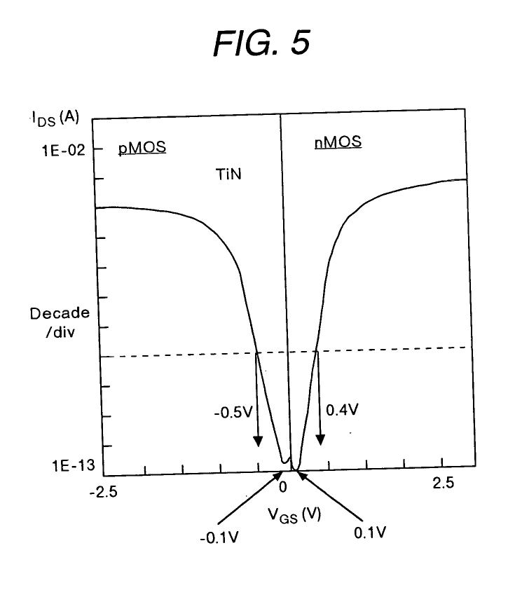

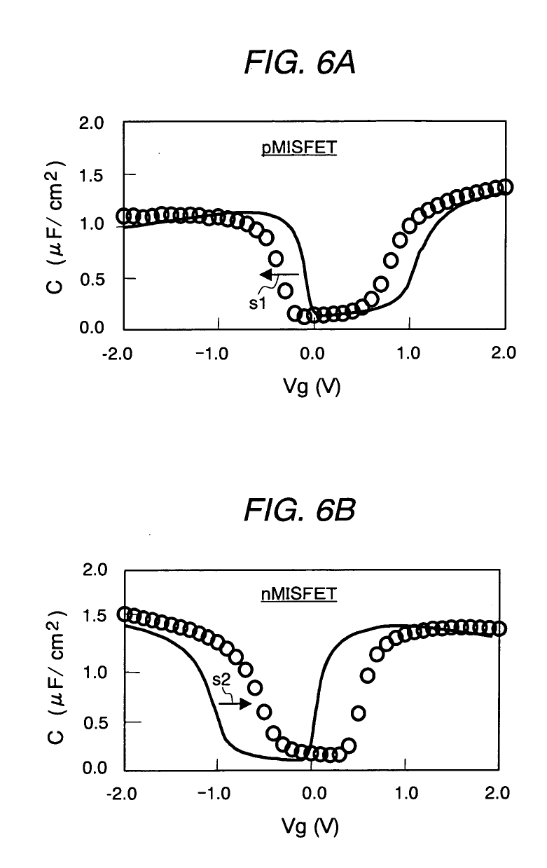

FIG. 1 is a completed cross-sectional view showing a first embodiment of a MISFET according to the present invention, and FIGS. 2A through 2C are respectively cross-sectional views showing manufacturing processes thereof in order. The present embodiment is characterized in that it is formed using a metal oxide gate insulating film corresponding to a high-K or dielectric material and an n-type polycrystalline silicon gate electrode to bring a threshold voltage Vth of an nMISFET of a thin-film SOI substrate to an enhancement type.

A method for manufacturing the MISFET of the present embodiment will be explained below using FIGS. 2A through 2C. As shown in FIG. 2A, a BOX (Buried Oxide) layer 8 made up of insulating SiO₂ is formed on a semiconductor substrate 1. Further, a substrate having an SOI layer 13 comprising a thin monocrystalline Si layer, which is provided on the BOX layer 8, is used. Incidentally, although substrates each having an SOI layer are not illustrated in particular with reference numerals given thereto in other embodiments to be described later, they are similar in structure to the substrate having the SOI layer 13 shown in FIG. 2A of the present embodiment.

In order to operate the SOI-MISFET at full depletion, there is a need to set the thickness of the SOI layer 13 to ⅓ to ¼ of a gate length. It is thus desirable that the thickness of the SOI layer is set to 25 nm or less in devices from a 100 nm node on down.

An STI (Shallow Trench Isolation) 2 is formed on the substrate 1 as each device isolation region using a silicon oxide film. Subsequently, an SiO₂ film 3 is formed 0.6 nm thick by a thermal process at 1000° C. in an oxygen gas ambiance. Thereafter, an Al₂O₃ film 4 of 1.0 nm is deposited thereon at 350° C. by an atomic layer deposition CVD method (ALCVD method) using H₂O as an oxidation gas with Tri-Methyl-Aluminum [Al(CH₃)₃] as a material gas.

According to the above process, a gate insulating film comprising the SiO₂ film 3 of 0.6 nm and the high-K insulating film (Al₂O₃ corresponding to a metal oxide in the present embodiment) 4 of 1.0 nm can be formed. It is desirable that an annealing process is continuously done for 30 seconds in a pressure-reduced oxygen gas ambiance at 1000° C. to recover defects in the Al₂O₃ film. Incidentally, a thermal process is done for, for example, about ten seconds at 900° C. in an NO gas ambiance before the formation of the Al₂O₃ film 4 after the formation of the 0.6 nm-thick SiO₂ film 3, and the SiO₂ film 4 may be replaced by silicon oxynitride (SION).

As the metal oxide 4, may be used here, a rare earth oxide film or rare earth silicate film such as Al, Zr, Hf, Y, La or the like, or a laminated film of an Al oxide film and a rare earth oxide film or rare earth silicate film such as Zr, Hf, Y, La formed on the Al oxide film, etc. The thickness thereof can suitably be changed.

Next, polycrystalline silicon is deposited and phosphorous, for example, is further ion-implanted therein in high concentration. Subsequently, a thermal process is done for two minutes in a nitrogen gas ambiance at 900° C., for example. After its thermal process, it is processed to a gate electrode structure to form an n-type low resistive polycrystalline silicon gate electrode 5 (see FIG. 2A). The n-type low resistive polycrystalline silicon gate electrode 5 does not present any problem if an In-Situ phosphorous doped polycrystalline Si film formed by performing deposition at a temperature of 630° C. using monosilane (SiH₄) and phosphine (PH₃) without performing the high-concentration ion implantation as described above is used therefor.

After the formation of the gate electrode 5, As ions are ion-implanted under conditions of an acceleration energy of 3 keV and an implantation rate of 1×10¹⁵ cm⁻² using the gate electrode 5 as a mask to thereby form n-type impurity diffusion layer regions 6 at their corresponding positions of source and drain regions (see FIG. 2B).

Next, for example, a silicon oxide film is deposited by a CVD (Chemical Vapor Deposition) method or the like. The resultant film is etched backed to form sidewalls 7.

Subsequently, an impurity activating process is performed by annealing. Although this process is done for about one second at 1000° C., for example, it is desirable that a processing time is set as short as possible and a heat history is shortened to thereby suppress the diffusion of impurities. After the annealing process, a metal silicide layer 9 is formed on surface layers of the diffusion layer regions 6 and the gate electrode 5 (see FIG. 2C) . As the silicide layer 9, for example, metal silicide such as titanium silicide, cobalt silicide, nickel silicide or the like can be used. After the formation of the metal silicide layer, an interlayer insulating film 10 and wiring electrodes 11 containing drain and source electrodes are formed in accordance with a desired circuit system, whereby the nMISFET having such a structure as shown in FIG. 1 is obtained.

In the present embodiment, the SOI substrate is used as the substrate that forms the MISFET, a channel region 12 is set to a low concentration of 10¹⁸ cm⁻³ or less as in the full depletion MISFET, and the threshold voltage Vth is controlled using a shift of a flatband voltage by introduction of the gate electrode 5 and the metal oxide film 4.

Since a reduction in carrier mobility with an increase in impurity scattering is suppressed due to the fact that the impurity concentration of the channel region 12 is held in the low concentration, a high-driven current-carrying operation can be expected. Further, as compared with the case in which the threshold voltage Vth of the MISFET is controlled by the impurity concentration of the channel region, a variation in threshold voltage Vth due to a statistical fluctuation in the number of impurities with respect to one MISFET can be reduced, and its threshold voltage Vth and power supply voltage can be both set low.

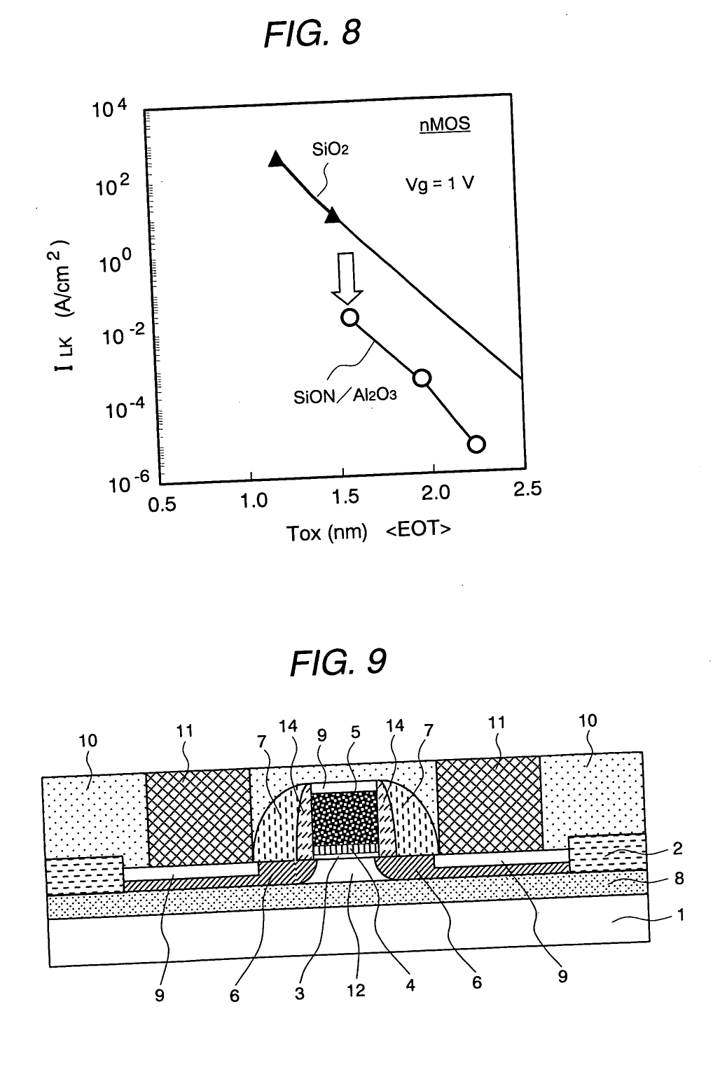

Since Al₂O₃ corresponding to the high-K insulating film is used as the gate insulating film, and the oxide film or oxynitride film is provided at an interface between the high-K insulating film and the channel region 12, agate leakage current I_{LX} can also be reduced as compared with the case of only the oxide film as is understood from the characteristic diagram of FIG. 8. It is therefore possible to achieve a reduction in power of the semiconductor device and its speeding-up. In FIG. 8, the horizontal axis Tox indicates an equivalent oxide thickness (EOT), and the vertical axis indicates a gate leakage current per unit area at the application of gate voltage VG=1V.

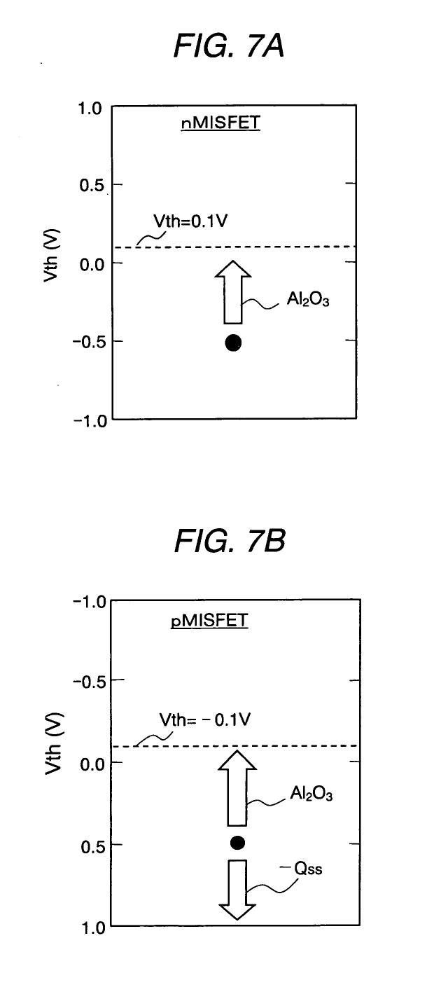

The structure of the MISFET according to the present embodiment can also be used to bring the threshold voltage Vth of a pMISFET formed in the thin-film SOI substrate to an enhancement type. Forming it by using the metal oxide gate insulating film corresponding to the high-K material and the p-type polycrystalline silicon gate electrode at this time makes it possible to control the threshold voltage of the pMISFET as shown in FIG. 7B.

Thus, even in the pMISFET, the impurity concentration of its channel region can be kept in low concentration and a reduction in carrier mobility with an increase in impurity scattering is restrained, in a manner similar to the nMISFET of the present embodiment. Therefore, a high-driven current-carrying operation can be expected. Further, a variation in threshold voltage Vth due to a statistical fluctuation in the number of impurities with respect to one MISFET can be reduced as compared with the case in which the threshold voltage Vth is controlled by the impurity concentration of the channel region, and its threshold voltage Vth and power supply voltage can be both set low. Since an oxide film or SiON film is provided at an interface between a high-K insulating film and a channel region, a gate leakage current is also be reduced. It is thus possible to achieve a reduction in power of the semiconductor device and its speeding-up.

### Second Preferred Embodiment

FIG. 9 is a cross-sectional view showing a second embodiment of a MISFET according to the present invention. Incidentally, the same constituent elements as those shown in FIG. 1 illustrative of the first embodiment are given the same reference numerals in FIG. 9, and their dual explanations are omitted. That is, a structure of the present embodiment is different from that of the first embodiment in that offset spacers 14 are added to their corresponding sidewalls of a gate electrode 5 as compared with the first embodiment.

In order to add such a structure, the polycrystalline silicon gate electrode 5 in the manufacturing process described in the first embodiment is formed and thereafter, for example, a silicon oxide film, silicon nitride, a titanium oxide film or the like is deposited about 10 nm thick by a CVD method. Then, the offset spacers 14 may be formed on their corresponding sidewalls of the gate electrode 5 by etching back this insulating film.

Subsequently, arsenic (As) ions are ion-implanted from this state under conditions of, for example, an acceleration energy of 3 keV and an implantation rate of 1×10¹⁵ cm⁻² with the offset spacers 14 as masks to thereby form n-type impurity diffusion layer regions 6 at their corresponding positions of source and drain regions. The deposited thickness of each offset spacer 14 can suitably be changed.

Processes all similar to the first embodiment are performed from the subsequent forming process of sidewalls 7, thereby leading to completion of the structure shown in FIG. 9.

Since the impurity diffusion layer regions 6 used as the source and drain regions are formed with the offset spacers 14 as the masks, the nMISFET of the present embodiment is capable of restraining horizontal spreading of the diffusion layer regions to a channel region 12, reducing overlapped areas of the gate electrode 5 and the impurity diffusion layer regions 6, and ensuring an effective channel length on a large scale. Therefore, the MISFET can be further miniaturized as compared with the first embodiment, and overlap capacitance between the gate electrode 5 and each impurity diffusion layer region 6 is kept small. It is therefore possible to reduce parasitic capacitance and provide further speeding-up of the MISFET as compared with the first embodiment.

It is of course possible to apply even the MISFET structure of the present embodiment to a pMISFET. Needless to say, the present embodiment also has the operations and effects described in the first embodiment in like manner in addition to the above advantages.

### Third Preferred Embodiment

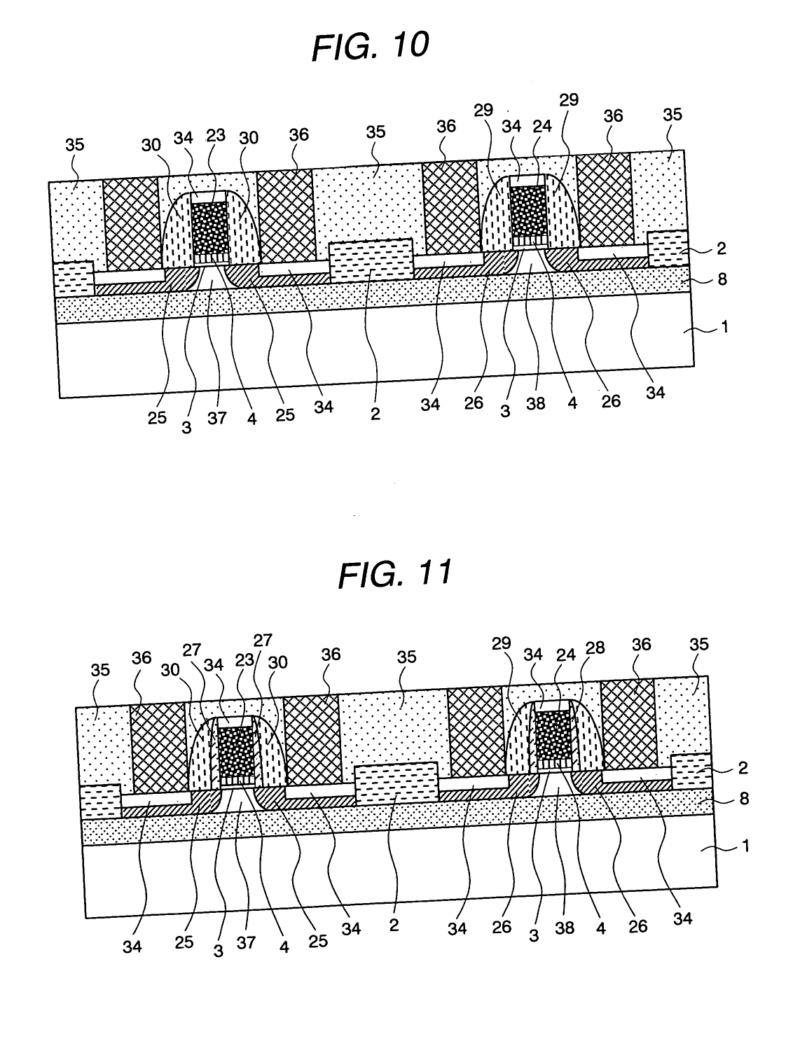

FIG. 10 is a cross-sectional view showing a third embodiment of a MISFET according to the present invention. The figure shows an embodiment in which both enhancement type n and pMISFETs each having a low threshold voltage (0.3V or less at an absolute value, and a target Vth=0.1V) are formed on the same substrate.

As shown in FIG. 10, a BOX layer 8 constituted of insulative SiO₂ is formed on a semiconductor substrate 1. Further, a substrate having an SOI layer made up of a thin Si layer, which is provided on the BOX layer 8, is used. In order to operate the SOI-MISFET at full depletion, there is a need to set the thickness of the SOI layer to ⅓ to ¼ of a gate length. It is thus desirable that the thickness of the SOI layer is set to 25 nm or less in devices from a 100 nm node on down.

An STI 2 is formed on the substrate 1 as each device isolation region using a silicon oxide film. Subsequently, an SiO₂ film 3 is formed 0.6 nm thick by a thermal process at 1000° C. in an oxygen gas ambiance. Thereafter, an Al₂O₃ film 4 of 1.0 nm is deposited thereon at 350° C. by an atomic layer deposition CVD method (ALCVD method) using H₂O as an oxidation gas with Tri-Methyl-Aluminum [Al(CH₃)₃] as a material gas.

According to the above process, a gate insulating film comprising the SiO₂ film 3 of 0.6 nm and the high-K insulating film (Al₂O₃ corresponding to a metal oxide in the present embodiment) 4 of 1.0 nm can be formed. It is desirable that an annealing process is continuously done for 30 seconds in a pressure-reduced oxygen gas ambiance at 1000° C. to recover defects in the Al₂O₃ film. Incidentally, a thermal process is done for, for example, about ten seconds at 900° C. in an NO gas ambiance before the formation of the Al₂O₃ film 4 after the formation of the 0.6 nm-thick SiO₂ film 3, and the SiO₂ film 4 may be replaced by silicon oxynitride film(SiON).

As the metal oxide 4, may be used here, a rare earth oxide film or rare earth silicate film such as Al, Zr, Hf, Y, La or the like, or a laminated film of an Al oxide film and a rare earth oxide film or rare earth silicate film such as Zr, Hf, Y, La formed on the Al oxide film, etc. The thickness thereof can suitably be changed.

Next, polycrystalline silicon is deposited and phosphorous, for example, is ion-implanted in a region that serves as the nMISFET in high concentration, and boron, for example, is ion-implanted in a region that serves as the pMISFET in high concentration. Subsequently, a thermal process is done for two minutes in a nitrogen gas ambiance at 900° C., for example. After its thermal process, it is processed to a gate electrode structure to form an n-type low resistive polycrystalline silicon gate electrode 23 and a p-type low resistive polycrystalline silicon gate electrode 24.

After the formation of the gate electrodes 23 and 24, for example, As ions are ion-implanted in the nMISFET from this state under conditions of an acceleration energy of 3keV and an implantation rate of 1×10¹⁵ cm⁻² with the gate electrode 23 as a mask to thereby form n-type impurity diffusion layer regions 25 at their corresponding positions of source and drain regions. Incidentally, when the As ions are implanted, for example, a photoresist covers the pMISFET region from above to prevent the As ions from being implanted therein.

Next, for example, BF₂ ions are ion-implanted in the pMISFET under conditions of an acceleration energy of 3 keV and an implantation rate of 1×10¹⁵ cm⁻² with the gate electrode 24 as a mask to thereby form p-type impurity diffusion layer regions 26 at their corresponding positions of source and drain regions. Next, for example, a silicon oxide film is deposited by a CVD method or the like and thereafter this insulating film is etched back to form sidewalls 29 and 30. Incidentally, when the BF₂ ions are implanted, the photoresist on the pMISFET region provided upon implantation of the As ions is removed and next, for example, a photoresist covers the nMISFET region from above to prevent the BF₂ ions from being injected therein.

Subsequently, an impurity activating process is performed by annealing. Although this process is done for about one second at 1000° C., for example, it is desirable that a processing time is set as short as possible and a heat history is shortened to thereby suppress the diffusion of impurities. After the annealing process, a metal silicide layer 34 is formed on each of surface layers of the diffusion layer regions 25 and 26 and the gate electrode 23 and 24. As the silicide layer, for example, metal silicide such as titanium silicide, cobalt silicide, nickel silicide or the like can be used. After the formation of the metal silicide layer, an interlayer insulating film 35 and wiring electrodes 36 containing drain and source electrodes are formed in accordance with a desired circuit system, whereby the complementary MISFET having such a structure as shown in FIG. 10 is obtained on the same SOI substrate.

Even in the present embodiment, the SOI substrate is used as the substrate that constitutes the MISFET, channel regions 37 and 38 are set to a low concentration of 10¹⁸ cm⁻³ or less as in the full depletion MISFET, and predetermined threshold voltages Vth are controlled at both n-channel MISFET and p-channel MISFET by using shifts of flatband voltages by introduction of the n-type polycrystalline silicon gate electrode 23 and the metal oxide film 4, and the n-type polycrystalline silicon gate electrode 24 and the metal oxide film 4.

When the shifts of the flatband voltages are used in this way, both threshold voltages of the n and pMISFETs can simultaneously be controlled by the conventionally widely-used n-type and p-type polycrystalline silicon gate electrodes without using the metal material.

Therefore, the following problems can be solved. That is, the solvable problems are as follows. A problem in which when a gate electrode is formed of a metal material and a threshold voltage Vth of a full depletion SOI-MISFET is controlled using a work function of the metal material, the threshold voltage Vth of the MISFET is inevitably determined by a device structure (channel impurity concentration, thickness of gate insulating film, etc.) of the MISFET where the material for the gate electrode is decided, so that only the MISFET having one kind of threshold voltage Vth can be fabricated where the gate electrode is simply formed of a metal.

Another problem in which when n and p MISFETs are simultaneously set to a target threshold voltage, there is a need to use metal materials respectively having individual work functions in the nMISFET and pMISFET, whereby a process increases in complexity.

A further problem in which when a metal material is applied, consistency with a conventional process lacks. These problems are solved.

Further, according to the present embodiment, a reduction in carrier mobility with an increase in impurity scattering is suppressed due to the fact that the impurity concentrations of the channel regions 37 and 38 are held in low concentration. Therefore, a high-driven current-carrying operation of the complementary MISFET can be expected.

Furthermore, as compared with the case in which the threshold voltage Vth of the MISFET is controlled by the impurity concentration of each channel region, a variation in threshold voltage Vth due to a statistical fluctuation in the number of impurities with respect to one MISFET can be reduced, and its threshold voltage Vth and power supply voltage can be both set low.

Since the high-K insulating film 4 is used as the gate insulating film, and the SiO₂ film or SiON film is provided at an interface between the high-K insulating film 4 and the channel region of the silicon substrate, a gate leakage current can also be reduced. It is therefore possible to achieve a reduction in power of the semiconductor device and its speeding-up.

### Fourth Preferred Embodiment

FIG. 11 is a cross-sectional view showing a fourth embodiment of a MISFET according to the present invention. The figure shows an embodiment in which both enhancement type n and pMISFETs each having a low threshold voltage (0.3V or less at an absolute value, and a target Vth=0.1V) are formed on the same substrate. Incidentally, the same constituent elements as those shown in FIG. 10 illustrative of the third embodiment are given the same reference numerals in FIG. 11, and their dual explanations are omitted. That is, a structure of the present embodiment is different from that of the third embodiment in that offset spacers 27 are added to their corresponding sidewalls of a gate electrode 23 of the nMISFET, and offset spacers 28 are added to their corresponding sidewalls of a gate electrode 24 of the pMISFET as compared with the third embodiment.

In order to add such a structure, the polycrystalline silicon gate electrode 23 and 24 in the manufacturing process described in the third embodiment are formed and thereafter, for example, a silicon oxide film, a silicon nitride film, a titanium oxide film or the like is deposited about 10 nm thick by a CVD method. Then, the offset spacers 27 and 28 may be formed on their corresponding sidewalls of the gate electrodes 23 and 24 by etching back this insulating film.

Subsequently, for example, As ions are ion-implanted in the nMISFET from this state under conditions of an acceleration energy of 3 keV and an implantation rate of 1×10¹⁵ cm⁻² with the gate electrode 23 and the offset spacers 27 as masks to thereby form n-type impurity diffusion layer regions 25 at their corresponding positions of source and drain regions. Incidentally, when the As ions are implanted, for example, a photoresist covers a pMISFET region from above to prevent the As ions from being implanted therein.

Next, for example, BF₂ ions are ion-implanted in the pMISFET under conditions of an acceleration energy of 3 keV and an implantation rate of 1×10¹⁵ cm⁻² with the gate electrode 24 and offset spacers 28 as masks to thereby form p-type impurity diffusion layer regions 26 at their corresponding positions of source and drain regions. Incidentally, when the BF₂ ions are implanted, the photoresist on the pMISFET region provided upon implantation of the As ions is removed and next, for example, a photoresist covers an nMISFET region from above to prevent the BF₂ ions from being implanted therein.

Next, a silicon oxide film, for example, is deposited by the CVD method and thereafter processes all similar to the third embodiment are performed from the process of etching back the insulating film to form sidewalls 29 and 30, thereby leading to completion of the structure shown in FIG. 11.

Even in the present embodiment, an SOI substrate is used as the substrate that constitutes the MISFET, channel regions 37 and 38 are set to a low concentration of 10¹⁸ cm⁻³ or less as in the full depletion MISFET, and predetermined threshold voltages Vth are controlled at both n-channel MISFET and p-channel MISFET by using shifts of flatband voltages by introduction of the n-type polycrystalline silicon gate electrode 23 and metal oxide film 4, and the p-type polycrystalline silicon gate electrode 24 and metal oxide film 4.

When the shifts of the flatband voltages are utilized in this way, both threshold voltages of the n and pMISFETs can simultaneously be controlled by the conventionally widely-used n-type and p-type polycrystalline silicon gate electrodes without using the metal material.

Therefore, the problems described in the third embodiment can also be solved in like manner. Further, the present embodiment brings about the following advantageous effects. That is, since the n-type impurity diffusion layer regions 25 and the p-type impurity diffusion layer regions 26 are formed with the offset spacers 27 and 28 as the masks, horizontal spreading of the diffusion layer regions to the channel regions 37 and 38 can be suppressed. Therefore, overlap areas between the n-type polycrystalline silicon gate electrode 23 and the n-type impurity diffusion layer regions 25 and between the p-type polycrystalline silicon gate electrode 24 and the p-type impurity diffusion layer regions 26 can be ensured small and effective channel lengths can be ensured on a large scale. Accordingly, the MISFET can be further scaled down as compared with the third embodiment.

Since overlap capacitances between the n-type polycrystalline silicon gate electrode 23 and each of the n-type impurity diffusion layer regions 25 and between the p-type polycrystalline silicon gate electrode 24 and each of the p-type impurity diffusion layer regions 26 can be held small, parasitic capacitance can be reduced and the MISFET can be further speeded up as compared with the third embodiment.

Besides, since the impurity concentrations of the channel regions 37 and 38 are held in a low concentration of 10¹⁸ cm⁻³ as in the full depletion MISFET, a reduction in carrier mobility with an increase in impurity scattering is suppressed, so that a high-driven current-carrying operation can be expected. Further, as compared with the case in which the threshold voltage Vth of the MISFET is controlled by the impurity concentration of each channel region, a variation in threshold voltage Vth due to a statistical fluctuation in the number of impurities with respect to one MISFET can be reduced, and its threshold voltage Vth and power supply voltage can be both set low. Since a high-K insulating film 4 is applied and an SiO₂ film or SiON film is provided at an interface between the high-K insulating film 4 and each channel region, a gate leakage current is also reduced. It is thus possible to achieve a reduction in power of a semiconductor device and its speeding-up.

While the preferred embodiments of the present invention have been explained above, the present invention is not limited to the above embodiments. It is of course possible to make various changes in design within the scope not departing from the spirit of the present invention.

According to the present invention, predetermined threshold voltages Vth can simultaneously be realized at both n and pMISFETs by using shifts of flatband voltages produced between polycrystalline silicon gate electrodes and metal oxides in a full depletion SOI-MISFET. It is also possible to make a reduction in power of a semiconductor device and its speeding-up compatible with each other.

What is claimed is:

1. A semiconductor device comprising:
a field effect transistor including,
a semiconductor substrate;
a semiconductor layer formed on the semiconductor substrate with an insulating film interposed therebetween;
source and drain regions formed in the semiconductor layer;
a channel region formed between the source and drain regions;
a gate insulating film formed over the channel region; and
a gate electrode formed through the gate insulating film,
wherein the gate insulating film is a gate insulating film formed using a metal oxide having a dielectric constant higher than a silicon oxide film, and
wherein the gate electrode comprises either a semiconductor film having the same conductivity type as the source and drain regions, or a laminated structure in which the semiconductor film and a high melting-point metal film are superimposed in order, or a laminated structure in which the semiconductor film and a high melting-point metal silicide film are superimposed in order.

2. The semiconductor device according to claim 1, wherein the metal oxide is any one selected from rare earth oxide films or rare earth silicate films such as Al, Zr, Hf, Y, La, etc.

3. The semiconductor device according to claim 1, wherein the metal oxide is a laminated film of an Al oxide film and any one selected from rare earth oxide films or rare earth silicate films such as Zr, Hf, Y, La, etc. formed on the Al oxide film.

4. The semiconductor device according to claim 1, wherein a silicon oxide film or silicon oxynitride film having a thickness of at least 0.5 nm is provided between the semiconductor layer and the gate insulating film.

5. The semiconductor device according to claim 1, wherein the thickness of the semiconductor layer that constitutes the channel region is less than or comparable to 25 nm.

6. The semiconductor device according to claim 1, wherein an impurity concentration of the channel region is 1×10¹⁸ cm⁻³ or less.

7. The semiconductor device according to claim 1, wherein offset spacers formed of an insulating film, and sidewalls formed of an insulating film, which are provided through the offset spacers, are respectively provided on sidewalls of the gate electrode.

8. A semiconductor device comprising:
a semiconductor substrate;
a semiconductor layer formed on the semiconductor substrate with an insulating film interposed therebetween;
first source and drain regions selectively formed in the semiconductor layer;
second source and drain regions selectively formed in the semiconductor layer;
a first channel region formed between the first source and drain regions;
a second channel region formed between the second source and drain regions;
a gate insulating film formed on the first and second channel regions;
a first gate electrode formed over the first channel region with the gate insulating film interposed therebetween; and
a second gate electrode formed over the second channel region with the gate insulating film interposed therebetween,
wherein the gate insulating film is a gate insulating film formed using a metal oxide having a dielectric constant higher than a silicon oxide film,
wherein the first gate electrode is either a first conductivity type semiconductor film identical to the first source and drain regions, or a laminated structure in which the first conductivity type semiconductor film and a high melting-point metal film are superimposed in order, or a laminated structure in which the first conductivity type semiconductor film and a high melting-point metal silicide film are superimposed in order, and
wherein the second gate electrode is either a second conductivity type semiconductor film identical to the second source and drain regions, or a laminated structure in which the second conductivity type semiconductor film and a high melting-point metal film are superimposed in order, or a laminated structure in which the second conductivity type semiconductor film and a high melting-point metal silicide film are superimposed in order.

9. The semiconductor device according to claim 8, wherein the metal oxide is any one selected from rare earth oxide films or rare earth silicate films such as Al, Zr, Hf, Y, La, etc.

10. The semiconductor device according to claim 8, wherein the metal oxide is a laminated film of an Al oxide film and any one selected from rare earth oxide films or rare earth silicate films such as Zr, Hf, Y, La, etc. formed on the Al oxide film.

11. The semiconductor device according to claim 8, wherein a silicon oxide film or silicon oxynitride film having a thickness of at least 0.5 nm is provided between the semiconductor layer and the gate insulating film.

12. The semiconductor device according to claim 8, wherein the thickness of the semiconductor layer that constitutes the first and second channel regions is less than or comparable to 25 nm.

13. The semiconductor device according to claim 8, wherein impurity concentrations of the first and second channel regions are 1×10¹⁸ cm⁻³ or less.

14. The semiconductor device according to claim 8, wherein offset spacers formed of an insulating film, and sidewalls formed of an insulating film, which are provided through the offset spacers, are respectively provided on sidewalls of the first and second gate electrodes.
